(19) United States
(12) Patent Application Publication
(10) Pub. No.: US 2008/0157248 A1
(43) Pub. Date: Jul. 3, 2008

(54) Image sensor and fabricating method thereof

(75) Inventor: Young Je Yun, Ansan-si (KR)

Correspondence Address: THE LAW OFFICES OF ANDREW D. FORTNEY, PH.D., P.C., 401 W FALLBROOK AVE STE 204, FRESNO, CA, 93711-5835, US

(73) Assignee: Dongbu HiTek Co., Ltd.

(21) Appl. No.: 12/001,646

(22) Filed: Dec. 11, 2007

(30) Foreign Application Priority Data
Dec. 27, 2006 (KR) 10-2006-0135714

(51) Int. Cl. H01L 31/0232; H01L 21/02

(52) U.S. Cl. 257/432; 438/70; 257/E31.127; 257/E21.002

(57) ABSTRACT

Disclosed is an image sensor and a method of fabricating the same, including a color filter layer having a red color filter, a green color filter and a blue color filter, a planarization layer which is formed on the color filter layer and has a groove corresponding to boundary areas between the color filters, and a micro-lens array on the planarization layer.

The present application claims priority under 35 U.S.C. 119 and 35 U.S.C. 365 to Korean Patent Application No. 10-2006-0135714 (filed on Dec. 27, 2006), which is hereby incorporated by reference in its entirety.

### BACKGROUND

Embodiments of the present invention relates to an image sensor and a method of fabricating the same. The image sensor is a semiconductor device designed to convert optical images into electrical signals. The image sensor includes a micro-lens array. The process for forming the micro-lens array exerts a great influence upon the performance of the image sensor. Related art image sensors may have a thick planarization layer (e.g., about 1 μm thick) on which the microlens array is formed. In the related art device the micro-lens may not be precisely aligned with features formed in lower layers of the image sensor.

### SUMMARY

Embodiments of the present invention provide an image sensor and a method of fabricating the same. The method can effectively fabricate a micro-lens array and improve the sensitivity of an image sensor device.

An image sensor according to one embodiment comprises a color filter layer having a red color filter, a green color filter and a blue color filter, a planarization layer which is formed on the color filter layer having grooves corresponding to boundary areas between the underlying color filters and a micro-lens array on the planarization layer.

A method of fabricating an image sensor according to one embodiment comprises forming a color filter layer having a red color filter, a green color filter and a blue color filter, forming a planarization layer on the color filter layer, forming grooves in the planarization layer corresponding to boundary areas between the color filters, forming a photoresist layer on the planarization layer, and forming the micro-lenses by heat-treating the photoresist layer.

### BRIEF DESCRIPTION OF THE DRAWINGS

FIG. 1 provides a cross-sectional view schematically representing a method of fabricating an image sensor including forming a color filter layer 11 and planarization layer 13.

FIG. 2 provides a cross-sectional view schematically representing a method of fabricating an image sensor including forming a photoresist layer 15 over planarization layer 13.

FIG. 3 provides a cross-sectional view schematically representing a method of fabricating an image sensor including forming a micro-lens array 15a.

### DETAILED DESCRIPTION OF THE EMBODIMENTS

In the following description of various embodiments, it will be understood that when a layer (or film), a region, a pad, a pattern or a structure are referred to as being ‘on/above’ another layer, region, pad, pattern or substrate, it can be directly on another layer, region, pad, pattern or substrate, or one or more intervening layers, regions, pads, patterns or structures may also be present. It will be further understood that when a layer (or film), a region, a pad, a pattern or a structure are referred to as being ‘under/below’ another layer, region, pad, pattern or substrate, it can be directly under layer, region, pad, pattern or substrate, and one or more intervening layers, regions, pads, patterns or structures may also be present. In addition, it will also be understood that when a layer (or film), a region, a pad, a pattern or a structure are referred to as being ‘between’ two layers, two regions, two pads, two patterns or two structures, it can be the only layer, region, pad, pattern or structure between the two layers, the two regions, the two pads, the two patterns and the two structures or one or more intervening layers, regions, pads, patterns or structures may also be present. Thus, the meaning thereof must be determined based on the scope of the present invention.

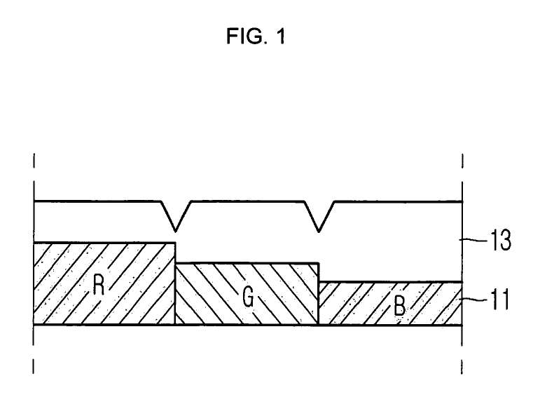

Hereinafter, an embodiment will be described in detail with reference to the accompanying drawings. FIGS. 1 to 3 are views schematically representing a method of fabricating an image sensor according to an embodiment of the present invention.

As shown in FIG. 1, according to an image sensor of one embodiment, a color filter layer 11 is formed on a substantially flat substrate (not shown). The color filter layer 11 has a width (e.g., the horizontal dimension as shown in FIG. 1) of about 2 microns. The color filter layer 11 includes a red color filter, a green color filter and a blue color filter. Alternatively, color filter layer 11 may includes yellow, cyan and magenta color filters.

The color filter layer 11 is formed such that the color filters have a step-like profile, as shown in FIG. 1. More specifically, the color filters may have different thicknesses over the substantially flat substrate. For example, a red color filter may have a greater thickness than a green color filter, and the green color filter may have a greater thickness than a blue color filter. Alternatively, the color filter layer 11 can be formed such that the color filters have substantially coplanar top surfaces.

A planarization layer 13 may be formed in the color filter layer 11. Grooves are formed on the planarization layer 13 corresponding to boundary areas between the color filters. The grooves may have different shapes. In one embodiment, the grooves have V-shapes. The grooves can be formed on the planarization layer 13 through an exposure process and a development process.

The planarization layer 13 may include a photoresist layer, such as a negative photoresist layer. In this manner, when the planarization layer 13 includes a negative photoresist layer, the grooves can be easily formed by patterning the photoresist layer to form a simple mask pattern (e.g., a pattern corresponding to the locations of the grooves) in or over a pixel region of the substrate. In various embodiments, the grooves have a width of from 0.15 μm to about 0.5 μm (e.g., about 0.3 μm in one implementation) at the upper surface of the planarization layer 13 The negative photoresist layer can be patterned by conventional photolithography techniques, including selective irradiation through the mask pattern for a period of time resulting in photoreaction through only part of the thickness of the planarization layer 13, and subsequent development. Alternatively or additionally, the planarization layer 13 may comprise a photoresist material that does not have sufficient resolution to form critical-dimension or minimum-resolution features. In such an embodiment, more light energy tends to be absorbed at or near the bottom of the planarization layer 13 than at its upper surface, resulting in V-shaped grooves in the planarization layer 13. However, the exact shape of the groove is not critical, as long as there is an indentation or trench of some kind in the planarization layer 13 over the interface between adjacent color filters. The mask may comprise a pattern of chromium lines on a quartz plate.

In another embodiment, the photoresist layer may be a transparent photoresist layer. Photolithographic irradiation using a mask with a pattern corresponding to the locations of the grooves for a predetermined period of time (e.g., an overexposure), followed by conventional development, can result in formation of the grooves in the planarization layer 13.

In one embodiment, the pattern of masking lines (e.g., chromium lines) may have a width corresponding to a critical dimension of the photolithographic processing equipment. The grooves are subsequently formed by a conventional exposure process. Forming the groove pattern using a mask pattern having a width of a critical dimension allows a subsequently formed microlens array to have substantially no gaps (e.g., horizontal gaps) between adjacent microlenses.

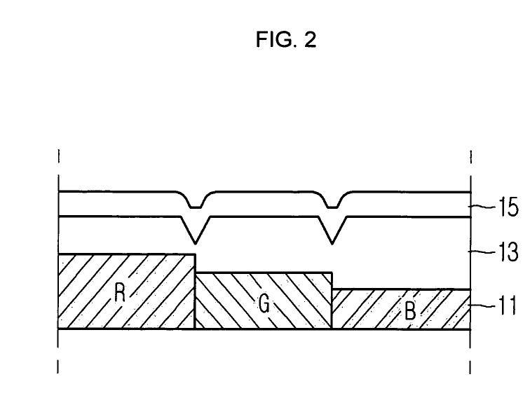

Next, as shown FIG. 2, according to one embodiment, a photoresist layer 15 for forming a microlens array is formed on the planarization layer 13. For instance, the photoresist layer 15 for forming the micro-lens can be formed by a coating process (e.g., spin-coating).

The photoresist layer 15 for forming the microlens array may include a conformal material. Accordingly, a topology of the planarization layer 13 on which the photoresist layer 15 is formed can be transferred to the photoresist layer 15. Next, a bulk exposure process (e.g., an irradiating the entire unmasked device) may be performed to disrupt cross-linking in the photo resist layer 15. In a further embodiment, photoresist layer 15 may be patterned to form a small gap in photoresist layer 15 above the grooves or trenches in the planarization layer 13, although such patterning is not required (especially in the photoresist layer 15 is a conformal layer).

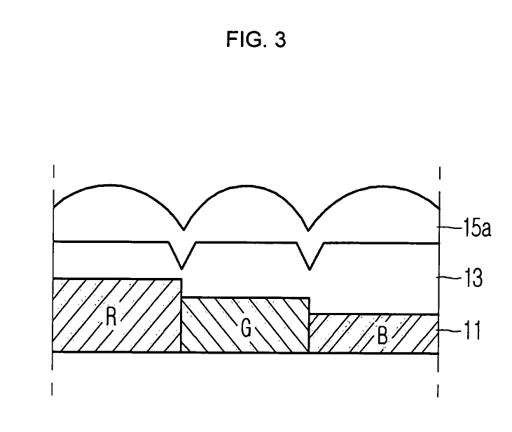

Subsequently, as shown in FIG. 3, according to the present method, an array of microlenses 15a is formed on the planarization layer 13 by heat-treating the photoresist layer 15 (e.g., by thermal reflow at a temperature of from about 120 to about 250° C., e.g. from about 150 to about 200° C.). The photoresist layer 15 hardens to form microlens array 15a, as shown in FIG. 3. The microlens array 15a features individual microlenses that correspond to the underlying color filters. The individual microlenses are formed such that there are substantially no horizontal gaps between adjacent microlenses. The surface of the microlens array 15a has boundaries between the individual microlenses that are aligned with and located above the grooves of the underlying planarization layer 13. The boundaries between the microlenses are also aligned with the boundaries between the underlying color filters. The present method

According to the embodiment of the present invention, the photoresist layer 15 for forming the micro-lens has a profile somewhat similar to that of a photoresist layer formed by an exposure process according to the related art. However, the related art method forms a microlens array by patterning a photoresist, such that horizontal gaps result between adjacent micro-lenses. Such horizontal gaps can be substantially eliminated by the method of the present invention. Furthermore, perhaps due to the shape and size (e.g., zero gap feature) of the microlenses being controlled by the existence of the grooves or trenches in the planarization layer 13, process margins are considerably improved relative to the related art process of patterning the microlens material, without requiring any additional process steps.

The above mentioned advantages can be achieved using largely the same process conditions as a related art method. If the micro-lens pattern is formed as described above, the alignment is performed in the process of forming the planarization layer pattern. Consequently, a precise alignment can be obtained as compared with a related art method in which the alignment is performed after forming a microlens-forming layer over a thick planarization layer.

In the micro-lens manufactured according to the method described above, a horizontal gap between the neighboring microlenses can be substantially eliminated. In addition, according to the embodiment, the lens is accurately aligned with respect to a lower layer.

As described above, the image sensor according to the embodiments of the present invention includes the color filter layer 11, the planarization layer 13 on the color filter layer 11, and the micro-lens array 15a on the planarization layer 13. The color filter layer 11 may include a red color filter, a green color filter and a blue color filter. The color filter layer 11 can be formed such that a step difference exists among the color filters. In another embodiment, the color filter layer 11 is formed such that the color filters have substantially co-planar top surfaces.

The planarization layer 13 is formed on the color filter layer 11, and the grooves formed in planarization layer 13 correspond to boundary areas between the color filters. The grooves may be formed in various shapes (e.g., the grooves may have V shapes). The planarization layer 13 may include a negative photoresist layer or a transparent photoresist layer.

The micro-lens array 15a is formed on the planarization layer 13. The micro-lens array is formed substantially free of horizontal gaps between the neighboring micro-lenses of the micro-lens array 15a. When the micro-lens array 15a is formed according to the embodiments of the present invention, the boundaries between the individual micro-lenses are aligned with the grooves of the planarization layer 13 and the boundaries between the underlying color filters.

According to embodiments of the present invention, the gap between neighboring micro-lenses can be substantially eliminated. In addition, according to the embodiment, the individual micro-lenses are accurately aligned the underlying color filters.

An image sensor including a micro-lens array fabricated according to embodiments of the present invention is effectively manufactured to have improved sensitivity.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. An image sensor comprising:
a color filter layer having first, second and third color filters, each of the first, second and third color filters having a different color;
a planarization layer which is formed on the color filter layer having grooves corresponding to boundary areas between the color filters; and
a micro-lens array on the planarization layer.

2. The image sensor as claimed in claim 1, wherein the planarization layer includes a negative photoresist layer.

3. The image sensor of claim 1, wherein the microlens array comprises a plurality of microlenses, each microlens corresponding to a unique color filter in the color filter layer.

4. The image sensor of claim 3, wherein boundaries between adjacent microlenses are aligned with the grooves in the planarization layer.

5. The image sensor as claimed in claim 1, wherein the color filters of the color filter layer have different thicknesses.

6. The image sensor as claimed in claim 1, wherein the micro-lens array has substantially no gaps between neighboring microlenses.

7. The image sensor as claimed in claim 1, wherein the first, second and third color filters comprise a red color filter, a green color filter and a blue color filter.

8. A method of fabricating an image sensor, the method comprising:
forming a color filter layer having first, second and third color filters, each of the first, second and third color filters having a different color;
forming a planarization layer on the color filter layer;
forming grooves in the planarization layer that are aligned with boundary areas between the color filters;
forming a photoresist layer on the planarization layer; and
forming a micro-lens array by heat-treating the photoresist layer.

9. The method as claimed in claim 8, wherein forming the grooves in the planarization layer comprises a photolithography exposure process.

10. The method as claimed in claim 8, wherein the color filters of the color filter layer have different thicknesses.

11. The method as claimed in claim 8, wherein the planarization layer comprises a negative photoresist layer.

12. The method as claimed in claim 8, wherein boundary areas between microlenses in the micro-lens array are aligned with the grooves of the planarization layer.

13. The method as claimed in claim 8, wherein the photoresist layer includes a conformal type material.

14. The method as claimed in claim 8, wherein forming the photoresist layer comprises a coating process.

15. The method of claim 14, wherein a topology of the planarization layer is transferred to the photoresist layer.

16. The method as claimed in claim 8, wherein the micro-lens array has substantially no gaps between neighboring micro-lenses.

17. The image sensor of claim 1, wherein the grooves have a V-like shape.

18. The method of claim 8, wherein forming the grooves in the planarization layer comprises patterning the negative photoresist layer.

19. The method of claim 18, wherein patterning the negative photoresist layer comprises irradiating the negative photoresist using a mask having a pattern thereon with a width equal to a critical dimension, then developing the irradiated photoresist.
